(19) United States
(12) Patent Application Publication
(10) Pub. No.: US 2025/0113500 A1
(43) Pub. Date: Apr. 3, 2025

(54) RESISTOR ARRANGEMENT AND TRANSISTOR DEVICE WITH RESISTOR ARRANGEMENT

(71) Applicant: Infineon Technologies Austria AG, Villach (AT)

(72) Inventors: Dan Horia Popescu, München (DE); Christian Fachmann, Villach (AT)

(21) Appl. No.: 18/891,638

(22) Filed: Sep. 20, 2024

(30) Foreign Application Priority Data
Sep. 29, 2023 (DE) 102023126720.5

(51) Int. Cl. H01L 27/06; H01L 29/78

(52) U.S. Cl. CPC H10D 1/47; H10D 30/668; H10D 84/811

(57) ABSTRACT

Disclosed is a resistor arrangement and a transistor device with a resistor arrangement. The resistor arrangement includes a resistive layer and first and second contact electrodes each formed on top of the resistive layer and each connected to the resistive layer. The first and second contact electrodes are spaced apart from each other in a first direction. Each of the first and second contact electrodes includes an inner section longitudinally extending in a second direction perpendicular to the first direction. The inner sections of the first and second contact electrodes are at least approximately parallel to each other. At least one of the first and second contact electrodes includes at least one end section adjoining the respective first section and being spaced apart from the other one of the first and second contact electrodes farther than a distance between the inner sections of the first and second contact electrodes.

### TECHNICAL FIELD

This disclosure relates in general to a resistor arrangement, in particular a resistor arrangement including a conducting resistive layer and to elongated contact electrodes.

### BACKGROUND

A resistor arrangement, in particular a resistor arrangement in integrated circuits, may include a resistive layer and two elongated contact electrodes that are each connected to the resistive layer and are parallel to each other. When a voltage is applied between the contact electrodes a current flows from one of the contact electrodes through the resistive layer to the other one of the contact electrodes. At the longitudinal ends of the contact electrodes, current crowding may occur. That is, a current density in the resistive layer at positions close to longitudinal ends of the contact electrodes may be higher than the current density at positions spaced apart from the longitudinal ends. This may have the effect that the resistive layer is unduly heated in areas close to the longitudinal ends of the contact electrodes. In particular when the resistor arrangement is part of an integrated circuit this may result in an overheating of portions of the integrated circuit and may result in reliability fails.

There is a need for a resistor arrangement in which current crowding at longitudinal end of elongated contact electrodes is avoided or at least reduced.

### SUMMARY

One example relates to a resistor arrangement. The resistor arrangement includes a resistive layer. Furthermore, the resistor arrangement includes a first contact electrode and a second contact electrode each formed on top of the resistive layer and each connected to the resistive layer. The first and second contact electrodes are spaced apart from each other in a first direction. Each of the first and second contact electrodes includes an inner section longitudinally extending in a second direction perpendicular to the first direction. The inner sections of the first and second contact electrodes are at least approximately parallel to each other, and at least one of the first and second contact electrodes includes at least one end section adjoining the respective first section and being spaced apart from the other one of the first and second contact electrodes farther than a distance between the inner sections of the first and second contact electrodes.

Another example relates to a transistor device with a gate resistor that is in accordance with such resistor arrangement.

### BRIEF DESCRIPTION OF THE DRAWINGS

Examples are explained below with reference to the drawings. The drawings serve to illustrate certain principles, so that only aspects necessary for understanding these principles are illustrated. The drawings are not to scale. In the drawings the same reference characters denote like features.

FIG. 1 schematically illustrates a cross-sectional view of a resistor arrangement including a resistive layer and two contact electrodes;

FIG. 2 schematically illustrates a top view of the contact electrodes according to one example;

FIGS. 3A-3B illustrate details of a first one of the contact electrodes;

FIGS. 4-7 illustrate top views of the contact electrodes according to further examples;

FIGS. 8-9 illustrate further examples of the resistor arrangement;

FIGS. 10A-10B illustrate examples of the contact electrodes in greater detail;

FIGS. 11A-11B illustrate further examples of the contact electrodes in greater detail;

FIGS. 12A-12A each illustrate a top view of a transistor device according to one example that includes a resistor arrangement connected between a gate pad and a gate runner;

FIG. 13 shows a vertical cross-sectional view of the resistor arrangement included in the transistor devices according to FIGS. 12A-12B;

FIGS. 14A-14B each show a top view of the resistive layer of the resistor arrangement included in the transistor devices according to FIGS. 12A-12B;

FIG. 15 illustrates a vertical cross sectional view of the gate runner and a portion of the resistive layer;

FIG. 16 illustrates an enlarged top view of the resistive layer and the contact electrodes;

FIG. 17 schematically illustrate vertical cross-sectional views of transistor cells according to one example; and

FIG. 18 schematically illustrates a horizontal cross-sectional view of the transistor cells illustrated in FIG. 17.

### DETAILED DESCRIPTION

In the following detailed description, reference is made to the accompanying drawings. The drawings form a part of the description and for the purpose of illustration show examples of how the invention may be used and implemented. It is to be understood that the features of the various embodiments described herein may be combined with each other, unless specifically noted otherwise.

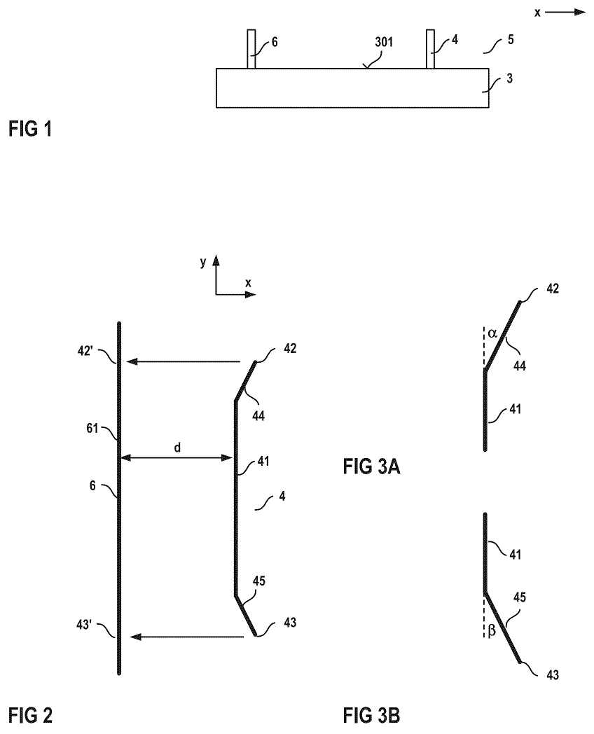

FIG. 1 schematically illustrates one example of a resistor arrangement that includes a resistive layer 3 and first and second contact electrodes 4, 6. More specifically, FIG. 1 schematically illustrates a vertical cross-sectional view of the resistor arrangement in a vertical section plane that is essentially perpendicular to a first surface 301 of the resistive layer 3.

Referring to FIG. 1, each of the first and second contact electrodes 4, 6 is formed on top of the resistive layer 3 and is (ohmically) connected to the resistive layer 3. The first and second contact electrodes 4, 6 are spaced apart from each other in a first direction x. The first direction x is a lateral direction, which is a direction that is essentially parallel to the first surface 301 of the resistive layer 3.

FIG. 2 schematically illustrates a top view of the first and second contact electrodes 4, 6 according to one example. In FIG. 2 only the first and second contact electrodes 4, 6 are schematically illustrated. The resistive layer 3 is not shown in this figure.

Referring to FIG. 2, each of the first and second contact electrodes 4, 6 includes an inner section 41, 61, wherein each of the inner sections 41, 61 longitudinally extends in a second direction y perpendicular to the first direction x. The second direction y is a lateral direction, which is a direction that is essentially parallel to the first surface 301 of the resistive layer 3. The inner sections 41, 61 of the first and second contact electrodes 4, 6 are at least approximately parallel to each other.

When a voltage is applied between the first and second contact electrodes 4, 6, a current may flow from one of the first and second contact electrodes 4, 6 through the resistive layer 3 to the other one of the first and second contact electrodes 4, 6. In order to prevent current crowding at longitudinally ends of the first and second contact electrodes 4, 6 at least one of the first and second contact electrodes 4, 6 includes at least one end section adjoining the respective inner section and being spaced apart from the other one of the first and second contact electrodes farther than a distance d between the inner sections 41, 61 of the first and second contact electrodes 4, 6. The distance d the (shortest) distance between the inner sections 41, 61 of the first and second contact electrodes 4, 6 in the first lateral direction x.

According to one example, the distance d between the inner sections 41, 61 is selected from a range of between 10 micrometers and several hundred micrometers, such as between 15 micrometers and 300 micrometers, for example. As explained herein further below, the distance d affects the resistance of the resistor arrangement. Basically, the resistance increases as the distance d increases.

In the example illustrated in FIG. 2, the first contact electrode 4, in addition to the inner section 41, includes a first end section 44 and a second end section 45. Each of the first and second end sections 44, 45 adjoins the inner section 41, wherein the first end section 44 is arranged between the inner section 41 and a first longitudinal end 42 of the first contact electrode 4 and the second end section 45 is arranged between the inner section 41 and a second longitudinal end 43 opposite the first longitudinal end 42.

In the example illustrated in FIG. 2, each of the first and second end sections 44, 45 is a straight electrode section that is inclined relative to the inner section 41 in such a way that each of the first and second end sections 44, 45 is spaced apart from the first contact electrode 6 farther than the distance d between the inner sections 41, 61. That is, a (shortest) distance between the first and second end sections 44, 45 and the second contact electrode 6 is larger than the distance d between the inner sections 41, 61.

FIGS. 3A and 3B show enlarged views of the first and second end sections 44, 45 and an adjoining portion of the inner section 41 of the first contact electrode 4. Referring to FIG. 3A, the first end section 44 section may be inclined relative to the inner section 41 by a first angle α. Referring to FIG. 3B, the second end section 45 may be inclined relative to the inner section 41 by a second angle R. According to one example, each of the first and second angles α, β is selected from a range of between 15° and 45°. The first and second angles α, β can have the same value or can have different values.

According to one example, a length of the inner section 41 of the first contact electrode 4 is at least 30 micrometers. The length of each of the first and second end sections 44, 45 is selected from a range of between 2 micrometers and 10 micrometers, for example. The first and second end sections 44, 45 can have the same length or can have different lengths.

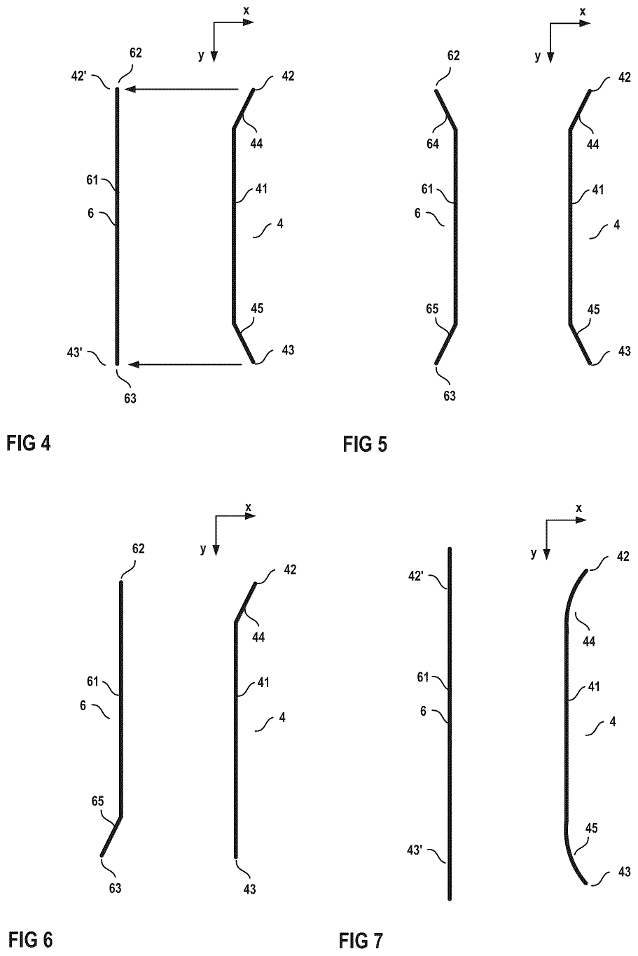

With regard to the first and second lateral directions x, y it should be noted that, unless stated otherwise, “first lateral direction” includes both the direction as indicated by the arrow labelled with x in FIG. 4 and the opposite direction. Equivalently, “second lateral direction” includes both the direction as indicated by the arrow labelled with y in FIG. 4 and the opposite direction.

In the example illustrated in FIG. 2, the second contact electrode 6 only includes a longitudinal section that is parallel to the inner section 41 of the first contact electrode 4. That is, the first contact electrode 6 only includes an inner section 61 in this example.

According to the example illustrated in FIG. 2, the second contact electrode 6 can be longer than the first contact electrode 4 in the second lateral direction y. That is, the second contact electrode 6 may extend, in the second lateral direction y, beyond a first projected end point 42′, which is obtained by projecting, in the first lateral direction x, the first end point 42 of the first contact electrode 4 onto the second contact electrode 6. Furthermore, the second contact electrode 6 may extend, in the second lateral direction y, beyond a second projected end point 43′, which is obtained by projecting, in the first lateral direction x, the second end point 43 of the first contact electrode 4 onto the second contact electrode 6.

According to one example, the second contact electrode 6, in the second lateral direction, extends beyond both the first and second projected end points 42′, 43′ by at least 10 micrometers, at least 50 micrometers, or at least 100 micrometers.

According to another example illustrated in FIG. 4, in the second lateral direction y, the second contact electrode 6 has the same dimension as the first contact electrode 4. This includes that the first projected end point 42′ of the first contact electrode 4 and a first end 62 of the second contact electrode 6 are essentially at the same position, and the second projected end point 43′ of the first contact electrode 4 and a second end 63 of the second contact electrode 6 are essentially at the same position.

FIGS. 5 and 6 illustrates top views of the first and second contact electrodes 4, 6 according to further examples. In each of these examples, the first and a second contact electrodes 4, 6 essentially have the same dimension in the second lateral direction y.

In the example illustrated in FIG. 5, both the first contact electrode 4 and the second contact electrode 6 have first and second end sections 44, 45, 64, 65. A first end section 64 of the second gate electrode 6 is an electrode section adjoining the inner section 61 and arranged between the inner section 61 and a first longitudinal end 62 of the second gate electrode. The second end section 65 of the second contact electrode 6 is an electrode section adjoining the inner section 61 and arranged between the inner section 61 and a second longitudinal end 63 of the second contact electrode 6. Everything explained herein before with regard to inclination angles and lengths of the first and second end sections 44, 45 of the first contact electrode 4 applies to the first and second end section 64, 65 of the second contact electrode 6 accordingly.

In the example illustrated in FIG. 6, each of the first and second contact electrodes 4, 6 has one end section, wherein the end sections are arranged on opposite ends of the first and second contact electrodes 4, 6. In the example illustrated in FIGS. 6, the first contact electrode 4 has a first end section 44 of the type explained herein before and arranged between the inner section 41 and the first longitudinal end 42. The second contact electrode 6 has a second end section 65 of the type explained herein before and arranged between the inner section 61 and the second longitudinal end 63.

In each of the examples explained herein before the resistivity of the resistor arrangement increases towards the first and second longitudinal ends 42, 43 of the first contact electrode 4. This is due to the fact that towards the first and second longitudinal ends of the first contact electrode 4 the distance between the first and second contact electrodes 4, 6 increases. This increase of the distance may be due to the first contact electrode 4 including at least one end section facing away from the second contact electrode 6 and/or the second contact electrode 6 including at least one end section facing away from the first contact electrode 4.

In the examples explained herein before, the at least one end section is a straight section. This, however, is only an example. According to another example the at least one end section is a curved electrode section. One example of a resistor arrangement including a contact electrode with curved end sections is illustrated in FIG. 7.

The resistor arrangement illustrated in FIG. 7 is based on the resistor arrangement illustrated in FIG. 2. Thus, the resistor arrangement illustrated in FIG. 7 includes a first contact electrode 4 with first and second end sections 44, 45 and includes a second contact electrode 6 that is longer than the first contact electrode 4 in the second lateral direction y and only includes a longitudinal inner section 61. However, this is only an example. In each of the examples explained herein before, one or more of the straight end sections 44, 45, 64, 65 may be replaced by a curved end section.

In each case, the first contact electrode 4 may entirely overlap the second contact electrode 6. That is, the projection of the first contact electrode 4 onto the second contact electrode 6 is arranged between first and second ends 62, 63 of the second contact electrode 6.

The resistive layer 3 is a conducting layer having a certain resistivity. According to one example, the resistive layer 3 is a doped polysilicon layer. The resistivity of the resistive layer is in a range of between 1 Ohm·m (Ω·m) and 20 Ohm·m, in particular between 3 Ohm·m and 10 Ohm·m, for example.

According to one example, a conductivity of the material of the first and second contact electrodes 4, 6 is at least 10 times the conductivity of the resistive layer 3. The conductivity is the reciprocal of the resistivity. According to one example, the first and second contact electrodes 4, 6 include a metal such as, for example, tungsten (W), titanium (Ti), aluminum (Al), copper (Cu), or an alloy made from two or more of these materials.

The resistance of the resistor arrangement is dependent on different parameters such as the distance d between the inner sections 41, 61 of the first and second contact electrodes; the resistivity of the resistive layer 3; the dimension of the resistor arrangement in the second lateral direction y; and the thickness of the resistive layer 3. The thickness of the resistive layer 3 is the dimension of the resistive layer in a direction perpendicular to the first surface 301. Basically, the larger the distance d, the higher the resistance; the higher the resistivity, the higher the resistance; the shorter the dimension of the resistor arrangement in the second lateral direction y, the higher the resistance; and the smaller the thickness of the resistive layer 3 the higher the resistance.

According to one example, the thickness of the resistive layer 3 is selected from a range of between 0.1 micrometers and 1 micrometer, in particular between 0.3 micrometers and 0.9 micrometers.

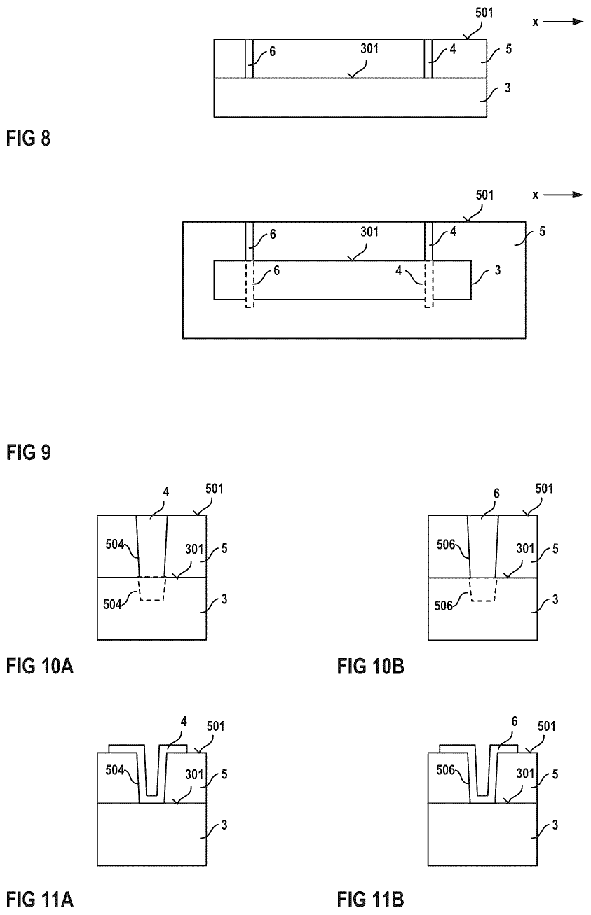

Referring to FIG. 8, each of the first and second contact electrodes 4, 6 may be arranged in a respective trench of an insulating layer 5 formed on top of the surface 301 of the resistive layer 3. Each of the first and second contact electrodes 4, 6 may extend, in the respective trench, from a surface 501 of the insulating layer 5 through the insulating layer 5 down to the resistive layer 3. The insulating layer is an oxide layer, for example.

According to one example illustrated in FIG. 9, the resistive layer 3 is embedded in the insulating layer 5.

Referring to the above, the first and second contact electrodes 4, 6 are in electrical contact with the resistive layer 3. For this, the first and second contact layers 4, 6 at least contact the resistive layer 3 at the surface of the resistive layer 3. However, the contact electrodes 4, 6 may also extend into the resistive layer 3 or even through the resistive layer 3. The latter is illustrated in dashed lines in FIG. 9.

The contact electrodes 4, 6 may be implemented in various ways. Different examples for implementing the contact electrodes 4 and 6 are illustrated in FIGS. 10A-10B and 11A-11B. Each of FIGS. 10A and 11A illustrates one example of the first contact electrode 4 in greater detail, and each of FIGS. 10B and 11B illustrates one example of the second contact electrode 6 in greater detail.

Referring to FIGS. 10A and 11A, the first contact electrode 4 is arranged in a first trench 504 extending from the surface 501 of the insulating layer 5 through the insulating layer 5 down to the resistive layer 3. Referring to FIG. 10A, the contact electrode 4 may completely fill the trench 504. According to another example illustrated in FIG. 11A, the contact electrode 4 may cover bottoms and sidewalls of the trench 504 but not completely fill the trench 504, so that a void remains in the trench 504. Optionally, the first contact electrode 4 also covers portions of the surface 501 of the insulating layer 5 in surface sections adjoining the trench 504.

Referring to FIGS. 10B and 11B, the second contact electrode 6 is arranged in a second trench 506 extending from the surface 501 of the insulating layer 5 through the insulating layer 5 down to the resistive layer 3. Referring to FIG. 10B, the contact electrode 6 may completely fill the trench 506. According to another example illustrated in FIG. 11B, the contact electrode 6 may cover bottoms and sidewalls of the trench 506 but may not completely fill the trench 506, so that a void remains in the trench 506. Optionally, the contact electrode 6 also covers portions of the surface 501 of the insulating layer 5 in surface sections adjoining the trench 506.

In the examples illustrated in FIGS. 10A-10B and 11A-11B, the first and second trenches extend to the surface of the resistive layer 3. This, however, is only an example. According to another example the trenches 504, 506 extend into the resistive layer 3 (as illustrated in dashed lines in FIGS. 10A and 10B) or even through the resistive layer 3.

The resistor arrangement explained herein before may be used as a resistor in various kinds of semiconductor devices or semiconductor arrangements that include a semiconductor body and at least one semiconductor device integrated in the semiconductor body. According to one example, the resistor arrangement is used as a gate resistor in a transistor device.

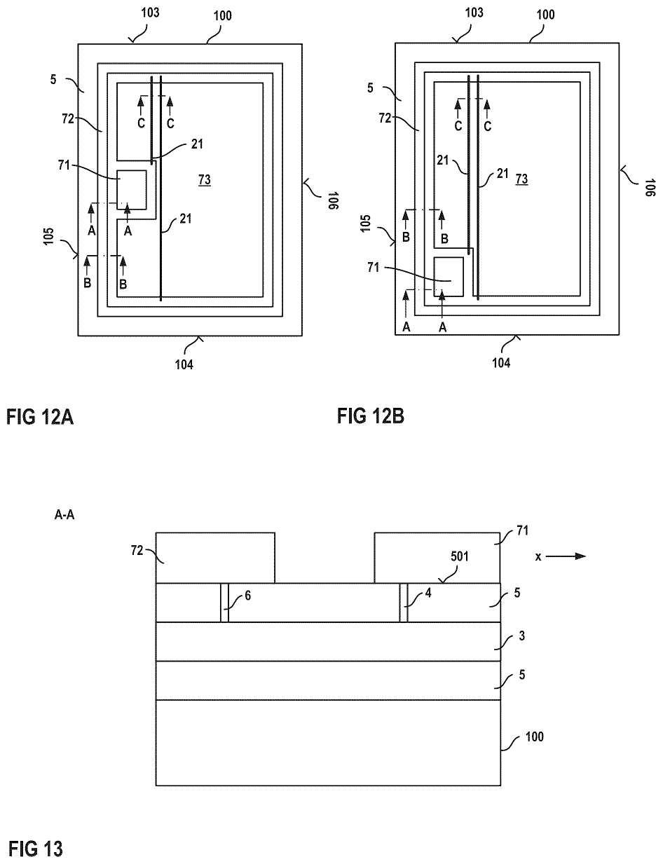

Each of FIGS. 12A and 12B illustrates a top view of a transistor device according to one example. The transistor device includes a gate pad 71 and a gate runner 72 that are spaced apart from each other and that are formed above a semiconductor body 100. In the example illustrated in FIG. 12A, the gate pad 71 is arranged at a position that is essentially in the middle between two opposing sidewalls 103, 104 of the semiconductor body 100. In the example according to FIG. 12B, the gate pad 71 is arranged at a position that is close to a corner formed by two adjacent sidewalls 104, 105 of the semiconductor body 100.

In each of the transistor devices according to FIGS. 12A and 12B, a resistor arrangement of the type explained herein before is connected between the gate pad 71 and the gate runner 72. This is illustrated in FIG. 13 which shows a vertical cross-sectional view of a portion of the transistor devices in a section plane A-A illustrated in FIGS. 12A-12B. As can be seen from FIG. 13, the resistive layer is embedded in an insulating layer 5 formed on top of the semiconductor body 100. That is, the resistive layer 3 is separated from the semiconductor body 100 by a first portion of the insulating layer 5 and is separated from the gate pad 71 and the gate runner 72 by a second portion of the insulating layer 5.

The first contact electrode 4 is connected to the gate pad 71 and the second contact electrode 6 is connected to the gate runner 72, so that the resistor arrangement acts as a gate resistor connected between the gate pad 71 and the gate runner 72 of the transistor devices. The first and second contact electrodes 4, 6 may be implemented in accordance with any of the examples explained herein before.

Referring to FIGS. 12A-12B, each of the transistor devices may further include a source electrode 73, wherein the gate runner 72, in horizontal directions, surrounds the source electrode 73. The semiconductor body 100 may include an inner region and an edge region. The inner region, which may also be referred to as active region, includes transistor cells and is essentially that region of the semiconductor body 100 arranged below the source electrode 73. Examples of the transistor cells are explained herein further below. The edge region is arranged between the inner region and sidewalls of the semiconductor body 100. According to one example, the gate runner 72 and the gate pad 71 are arranged above the edge region of the semiconductor body 100.

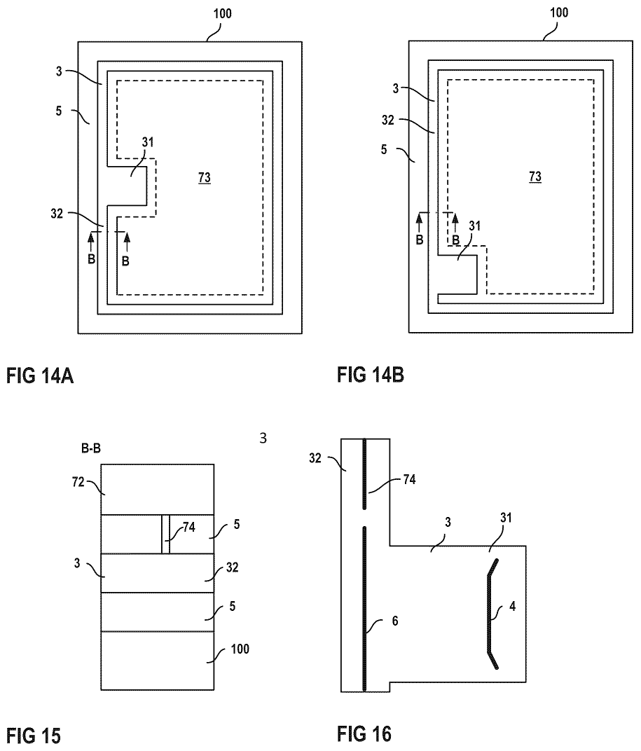

FIGS. 14A-14B illustrate horizontal cross-sectional views of the transistor devices according to FIGS. 12A-12B in a horizontal plane that cuts through the insulating layer 5 and the resistive layer 3. The position of the source electrode 73 relative to the resistive layer 3 is illustrated in dashed lines in FIGS. 14A-14B.

In the examples illustrated in FIGS. 14A-14B, the resistive layer 3 is a contiguous layer that includes a first portion 31 that essentially has the form of the gate pad 71 and is arranged below the gate pad 71, and a second portion 32 that essentially has the form of the gate runner 72 and is arranged below the gate runner 72.

FIG. 15 illustrates a vertical cross-sectional view of one portion of each of the transistor devices illustrated in FIGS. 12A-12B in a vertical section plane B-B that cuts through the gate runner 72 and the first section 31 of the resistive layer 3. Referring to FIG. 15, the gate runner 72 may be electrically connected to the resistive layer 3 through an electrically conducting via 74 extending from the gate runner 72 through the insulating layer 5 to the resistive layer 3, in particular, to the second section 32 of the resistive layer 3.

FIG. 16 shows an enlarged top view of the first section 31 and an adjoining portion of the second section 32 of the resistive layers 3. The first and second contact electrodes 4, 6 of the resistor arrangement are also illustrated in FIG. 16. Furthermore, one example of the contact via 74 connecting the first section 31 of the resistive layer 3 to the gate runner 72 is also illustrated in FIG. 16.

Referring to FIG. 16, the contact via 74 may be spaced apart from the second contact electrode 6 of the resistor arrangement. This, however, is only an example. According to another example (not illustrated), the contact via 74 adjoins the second contact electrode 6. According to yet another example (not illustrated), the transistor device includes a plurality of contact vias 74 that are spaced apart from each other and connect the second section 31 of the resistive layer 3 to the gate runner 72.

Referring to the above, the transistor device may include a plurality of transistor cells arranged in an inner region of the semiconductor body 100 below the source electrode 73. FIG. 17 schematically illustrates transistor cells 10 according to one example. More specifically, FIG. 17 illustrates a vertical cross-sectional view of one portion of the semiconductor body 100 in which transistor cells 10 are formed. The section plane C-C in FIG. 17 corresponds to section planes C-C illustrated in FIGS. 12A-12B.

According to one example, the semiconductor body 100 includes a monocrystalline semiconductor material. The semiconductor material is silicon (Si) or silicon carbide (SiC), for example.

Referring to FIG. 17, each transistor cell 10 includes a source region 11 of a first doping type, a body region 12 of a second doping type complementary to the first doping type, and a gate electrode 21. The gate electrode 21 is adjacent to the body region 12, is dielectrically insulated from the body region 12 by a gate dielectric 22, and is arranged in a gate trench 120 extending from a first surface 101 of the semiconductor body 100 into the semiconductor body 100.

Referring to FIG. 17, source and body regions 11, 12 of two neighboring transistor cells 10 may be arranged in a mesa region between neighboring gate trenches 120. In this example, the body regions 12 of the two neighboring transistor cells 10 may be formed by one contiguous doped region of the second doping type. Furthermore, two (other) neighboring transistor cells may share the gate electrode 21. That is, the gate electrodes 21 of two neighboring transistor cells may be formed by one contiguous electrode arranged in one gate trench 120.

The gate electrodes 21 include an electrically conducting material. Examples of the electrically conducting material include doped polysilicon, or a metal such as tungsten (W), titanium (Ti), copper (Cu), aluminum (Al), or the like. The gate dielectric 22 includes an oxide, for example. According to one example, the oxide is silicon oxide (SiO₂). The source electrode 73 includes an electrically conducting material such as, for example, aluminum (Al), copper (Cu), or an aluminum-copper alloy (AlCu).

The source electrode 73 is electrically connected to the source and body regions 11, 12 of the transistor cells 10. Connections between the source electrode 73 and the source and body regions 11, 12 are only schematically illustrated in FIG. 17. Such connections may be implemented using electrically conducting vias that extend from the source electrode 73 through the insulating layer 5 to the source and body regions 11, 12. This is commonly known, so that no further explanation is required in this regard.

Referring to FIG. 17, the transistor device further includes a drain region 13 of the first doping type and a drift region 14 of the first doping type. The drift region 14 adjoins the body regions 12 so that the PN junctions are formed between the body regions 12 and the drift region 14.

Optionally, a buffer region 16 of the first doping type and having a doping concentration that is higher than the doping concentration of the drift region 14 and lower than the doping concentration of the drain regions 13 is arranged between the drift region 14 and the drain regions 13.

The transistor device according to FIG. 1 is a vertical transistor device. In this example, the drain region 13 is spaced apart from the source and body regions 11, 12 of the transistor cells 10 in a vertical direction z of the semiconductor body 100. The vertical direction z is essentially perpendicular to the first surface 101 of the semiconductor body 100. According to one example, the drain region 13 adjoins a second surface 102 opposite the first surface 101 of the semiconductor body 100.

Referring to FIG. 17, the gate trenches with the gate electrodes 21 are spaced apart from each other in a first lateral direction x1 of the semiconductor body 100. The first lateral direction x1 is perpendicular to the vertical direction z of the semiconductor body 100. According to one example, the gate electrodes 21 are implemented as stripe electrodes (elongated electrodes). In this example, the gate electrodes 21, in a second lateral direction y1 perpendicular to the first lateral direction x1, are elongated.

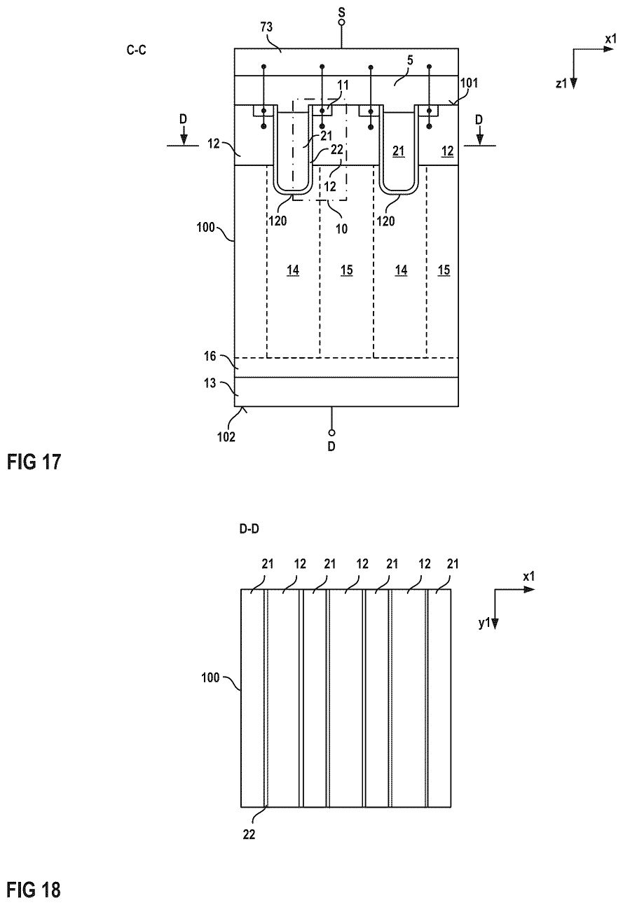

One example of elongated gate electrodes 21 is illustrated in FIG. 18. FIG. 18 illustrates one portion of the semiconductor body 100 in a first horizontal section plane D-D according to FIG. 17 that cuts through the gate trenches 120 with the gate electrodes 21 and the gate dielectrics 22.

According to one example, the transistor device is implemented as a superjunction transistor device. In this example, the transistor device includes a plurality of compensation regions 15 (illustrated in dashed lines) that are spaced apart from each other in the first lateral direction x1 of the semiconductor body 100. Each of the compensation regions 15 is adjacent a respective portion of the drift region 14. Just for the purpose of illustration, in the example illustrated in FIG. 15, the compensation regions 15 are spaced apart from each other in the first lateral direction xL. According to another example (not illustrated) the compensation regions 50 are spaced apart from each other in the second lateral direction y1.

The transistor device can be operated in an on-state or an off-state. In the on-state, there are conducting channels in the body regions 12 along the gate dielectrics between the source regions 11 and the drift regions 14. For this, the drift regions 14 adjoins the gate dielectric 22 and the body region 12 of at least one of the transistor cells 10. Each of the compensation regions 15 is adjacent to at least one of the drift regions 15 and is connected to the source electrode 41. In the example illustrated in FIG. 17, each of the compensation regions 15 adjoins the body region 12 of at least one transistor cell and is connected to the source electrode 41 via the respective body region 12.

The drain region 13 forms a drain node D or is connected to a drain node D of the transistor device. The source electrode 73 forms a source node S or is connected to a source node S of the transistor device. Furthermore, the gate electrodes 21 are connected to the gate pad 71, which forms a gate node G of the transistor device.

The transistor device can be operated in a conventional way by applying a drive voltage (gate-source voltage) between the gate electrodes 21 and the source electrode 41. The transistor device is in the on-state (conducting state) when the drive voltage is such that conducting channels are generated in the body regions 12 along the gate dielectrics 22 between the source regions 11 and the drift regions 14. The transistor device is in the off-state (blocking state) when the electrically conducting channels are interrupted.

The transistor device can be implemented as an N-type transistor device or as a P-type transistor device. An N-type transistor device, for example, is in the on-state, when the drive voltage is higher than a predefined positive threshold voltage and in the off-state, when the drive voltage is below the threshold voltage.

In an N-type transistor device, the doped regions of the first doping type are N-type regions and the doped regions of the second doping type are P-type regions. In a P-type transistor device, the doped regions of the first doping type are P-type regions and the doped regions of the second doping type are N-type regions.

The source regions 11, the body regions 12, the drift and compensation regions 14, 15, the buffer region 16, and the drain region 13 may also be referred to as active device regions. In an N-type transistor device, doping concentrations of the active device regions are selected from the following ranges, for example
Source region 11: 5E19 cm⁻³-5E20 cm⁻³
Body region 12: 3E19 cm⁻³-3E20 cm⁻³
Drain region 13: 5E18 cm⁻³-5E20 cm⁻³
Drift region 14: 7E15 cm⁻³-7E16 cm⁻³
Compensation region 15: 7E15 cm⁻³-7E16 cm⁻³
Buffer region 16: 5E15 cm⁻³-5E16 cm⁻³
Body contact region 17: 1E20 cm⁻³-1E21 cm⁻³

In FIGS. 12A-12B, the transistor cells 10 are out of view. Just for the purpose of illustration, the position of two of the plurality of gate electrodes 21 relative to the source electrode 73 and the gate runner 72 are illustrated by bold lines. Each of the gate electrodes 21 is electrically connected to the gate runner 72 at at least one longitudinal end. In the examples illustrated in FIGS. 12A-12B, longitudinal ends of the gate electrodes 21 are connected to the gate runner 72 in regions close to sidewalls 103, 104.

According to one example, the gate electrodes 21 are connected to the second section 32 of the resistive layer 3, which is connected to the gate runner 72 through the one or more contact vias 74. According to one example, the contact vias 74 and the gate runner 72 have a higher conductivity than the resistive layer 3, so that in those regions where the second section 32 of the resistive layer 3 is parallel to the gate runner 72. Thus, a majority of a current from the gate pad 71 to or from the gate electrodes 21 flows in the gate runner 72. Between the gate runner 72 and the gate pad 71 the current flows through the resistor arrangement which has the first contact electrode 4 connected to the gate pad the 71 and the second contact electrode 6 connected to the gate runner 72.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A resistor arrangement, comprising:
a resistive layer;
a first contact electrode and a second contact electrode each formed on top of the resistive layer and each connected to the resistive layer,
wherein the first and second contact electrodes are spaced apart from each other in a first direction,
wherein each of the first and second contact electrodes comprises an inner section longitudinally extending in a second direction perpendicular to the first direction,
wherein the inner sections of the first and second contact electrodes are at least approximately parallel to each other, and
wherein at least one of the first and second contact electrodes comprises at least one end section adjoining the respective first section and being spaced apart from the other one of the first and second contact electrodes farther than a distance between the inner sections of the first and second contact electrodes.

2. The resistor arrangement of claim 1,
wherein the at least one end section comprises first and second end sections of the first contact electrode,
wherein the first end section is arranged between the inner section and a first longitudinal end of the first contact electrode, and
wherein the second end section is arranged between the inner section and a second longitudinal end of the first contact electrode.

3. The resistor arrangement of claim 2,
wherein the second contact electrode is longer than the first contact electrode in the second direction.

4. The resistor arrangement of claim 3,
wherein the second contact electrode extends, in the second direction, beyond both the first longitudinal end and the second longitudinal end of the first contact electrode by at least 5 micrometers.

5. The resistor arrangement of claim 2,
wherein the at least one end section further comprises first and second end sections of the second contact electrode,
wherein the first end section is arranged between the inner section and a first longitudinal end of the second contact electrode, and
wherein the second end section is arranged between the inner section and a second longitudinal end of the second contact electrode.

6. The resistor arrangement of claim 1,
wherein the first contact electrode comprises an end section spaced apart from the inner section of the second contact electrode in the first lateral direction, and
wherein the second contact electrode comprises an end section spaced apart from the inner section of the first contact electrode in the first lateral direction.

7. The resistor arrangement of claim 1,
wherein the at least one end section is straight.

8. The resistor arrangement of claim 1,
wherein the at least one end section is curved.

9. The resistor arrangement of claim 1,
wherein a length of the at least one end section is between 3 micrometers and 10 micrometers.

10. The resistor arrangement of claim 1,
wherein a length of the inner section of each of the first and second contact electrodes is at least 10 micrometers, at least 20 micrometers, or at least 50 micrometers.

11. The resistor arrangement of claim 1,
wherein the distance between the inner sections of the first and second contact electrodes is at least 30 micrometers.

12. The resistor arrangement of claim 1,
wherein the resistive layer comprises doped polysilicon.

13. The resistor arrangement of claim 1,
wherein at least one of the first and second contact electrodes comprises a metal.

14. The resistor arrangement of claim 13,
wherein the metal is selected from the group consisting of:
tungsten;
titanium;
aluminum; and
copper.

15. The resistor arrangement of claim 1,
wherein each of the first and second contact electrodes is arranged in a respective trench of an insulating layer formed on top of the resistive layer.

16. The resistor arrangement of claim 15,
wherein the resistive layer is embedded in the insulating layer.

17. A transistor device, comprising:
a gate pad and a gate runner spaced apart from each other and each formed above a semiconductor body; and
the resistor arrangement of claim 1,
wherein the first contact electrode of the resistor arrangement is connected to the gate pad and the second contact electrode of the resistor arrangement is connected to the gate runner.

18. The transistor device of claim 17, further comprising:
a plurality of transistor cells each comprising active regions formed in the semiconductor body and each comprising a gate electrode,
wherein the gate electrodes of the transistor cells are electrically connected to the gate runner.

19. The transistor device of claim 18, wherein the active regions of each of the transistor cells comprise:
a source region of a first doping type; and
a body region of a second doping type complementary to the first doping type.

20. The transistor device of claim 19, further comprising:
at least one a drift region of the first doping type adjoining the body region of at least one of the transistor cells.
